(19) United States
(12) Patent Application Publication
(10) Pub. No.: US 2002/0036349 A1
(43) Pub. Date: Mar. 28, 2002

(54) Semiconductor device and manufacturing

(75) Inventors: Kenji Saito, Tokyo (JP); Kazuhiko Sanada, Tokyo (JP)

Correspondence Address: SUGHRUE,MION, ZINN,MACPEAK & SEAS, 2100 Pennsylvania Avenue, N.W., Washington, DC, 20037, US

(73) Assignee: NEC CORPORATION

(21) Appl. No.: 09/964,499

(22) Filed: Sep. 28, 2001

(30) Foreign Application Priority Data
Sep. 28, 2000 (JP) 297309/2000

(51) Int. Cl. H01L 23/48; H01L 23/52; H01L 29/40

(52) U.S. Cl. 257/758

(57) ABSTRACT

A semiconductor device having a multi-layer wiring structure is provided. In the device, a void for reducing parasitic capacitance between wirings of the device is formed in an interlayer insulating film. When a contact holes passes through the void, adjacent bit lines would ordinarily be short-circuited through metal entering the void between the contact holes. However, in the semiconductor device, a side wall insulating film is formed on an inner wall of a contact holes. Thus, the contact holes can connect a diffusion layer and a bit line and can intersect a void without creating a short circuit. Thus, it is possible to reduce short circuits occurring through the contact holes between the bit lines and to reduce parasitic capacitance between the wirings.

### BACKGROUND OF THE INVENTION

1. Field of the Invention

The present invention generally relates to a semiconductor device having a multi-layer wiring and particularly, but not limited to, a semiconductor device having a cavity or a void provided in an interlayer insulating film, which is located between wirings, to reduce a capacity between the wirings. Also, the invention generally relates to manufacturing method of the device. The present application is based on Japanese Patent Application No. 297309/2000, which is incorporated herein by reference.

2. Description of the Related Art

In order to reduce a capacitance between wirings in a semiconductor device, a configuration has been proposed in which a cavity or a void is formed in an interlayer insulating film between the wirings. Such void is formed along and in parallel with the wirings to reduce the capacitance between the wirings.

A method of forming a void between wirings in a semiconductor device is disclosed in Japanese Patent Application Laid-Open No. Heisei 9-186232. However, as explained in more detail below, when a through hole is formed through an interlayer insulating film and intersects the void, a short circuit may likely occur in the device. Therefore, the location of the through hole has to be arranged so that the through hole does not intersect a void. Such requirement increases the complexity and cost of manufacturing the semiconductor device.

A specific example of such problem is shown in FIGS. 1A and 1B. FIG. 1A is a sectional view of a flash memory device taken at the center of a bit line along the length of the bit line. FIG. 1B is a sectional view of the device taken at the center of the bit line in a direction perpendicular to the length of the bit line.

As shown in the figures, wells (not shown) and field oxide films 202 are formed on a semiconductor substrate 201. Then, tunnel oxide films 203, floating gates 204, ONO films 205 (i.e. laminated films of a silicon oxide film, a silicon nitride film, and a silicon oxide film), and control gates 206 are sequentially formed on the substrate 201. The films 203 to 205 and gates 206 form word lines 231, and the word lines 231 extend parallel to each other. In addition, source and drain diffusion layers 207 are formed between the word lines 231.

Then, side walls 208 are formed on the sides of the word lines 231, and non-doped silicon oxide films 209 are formed between the word lines but do not completely fill the space between the word lines 231. However, the films 209 are thick enough to prevent impurities from diffusing to the semiconductor substrate 201 from layers above the films 209.

Subsequently, boron phosphorus silicate glass (“BPSG”) films 210 are grown over the oxide films 209. The BPSG films 210 contain boron and phosphorus impurities, and the non-doped silicon oxide films 209 prevent such impurities from travelling to the substrate 201.

Next, a heating operation is performed, the BPSG films 210 are subjected to reflowing, a chemical mechanical polishing (“CMP”) operation is performed on the BPSG films 210, and the unevenness on the BPSG films 210 are eliminated to flatten surfaces thereof.

During the above operations, voids 211 (or “nests”) running between and in parallel with the word lines 231 are formed in the BPSG films 210. Such voids 211 can be formed by adjusting a concentration of phosphorus and boron, a reflowing temperature, and reflowing time when the BPSG films 210 are grown.

Subsequently, in order to expose the source and drain diffusion layer 207, a contact hole 212 is formed. The contact hole 212 penetrates the BPSG film 210 and reaches the source and drain diffusion layer 207. The contact hole 212 ideally should not intersect any voids 211. However, as shown in FIG. 1B, the contact hole 212 may intersect a void 211 due to a displacement error or other errors in manufacturing.

Next, the inner surfaces of the contact hole 212 are cleaned, and a laminated metal film 215 made of a composite material including titanium/titanium nitride is sputtered as a contact layer. Thereafter, tungsten 216 is filled in the contact hole 212, and a bit line 232 is formed over the layer to complete a flash memory semiconductor device.

In the flash memory device described above, if the depth of the contact hole 212 is small or if the void 211 has a large diameter, the laminated metal film 215 or an inner-void metal 217 made of the tungsten 216 may be formed in the void 211 between the contacts 212. Thus, when the contact hole 212 passes through the void 211, adjacent bit lines 232 are short-circuited to each other through the laminated metal film 215 or the inner-void metal 217.

### SUMMARY OF THE INVENTION

One illustrative, non-limiting embodiment of a semiconductor device of the present invention has a basic configuration including: a base substrate having a lower conductive layer formed thereon; an interlayer insulating film covering the base substrate; openings which penetrate the interlayer insulating film and reach the lower conductive layer; and an upper conductive layer which is formed on the interlayer insulating film and connects to the lower conductive layer via the openings. A linear cavity is formed in the interlayer insulating film, and the opening includes a cavity intersecting opening, which is opened through the linear cavity.

One illustrative, non-limiting embodiment of a manufacturing method of the semiconductor device of the present invention includes: forming the lower conductive layer in the base substrate; covering the base substrate with the interlayer insulating film; forming the openings penetrating the interlayer insulating film and reaching the lower conductive layer; and forming the upper conductive layer which is formed on the interlayer insulating film and connects to the lower conductive layer via the openings.

### BRIEF DESCRIPTION OF THE DRAWINGS

Features of the illustrative, non-limiting embodiments of the present invention will be more apparent from the following description taken in conjunction with the accompanying drawings, in which:

FIG. 1A is a sectional view showing a semiconductor device of the related art;

FIG. 1B is another sectional view showing a semiconductor device of the related art;

FIG. 2A is a plan view showing a semiconductor device according to a first illustrative embodiment of the present invention;

FIG. 2B is a sectional view, taken along lines I-I′ in FIG. 2A;

FIG. 2C is a sectional view, taken along lines II-Il′ in FIG. 2A;

FIG. 2D is a sectional view, taken along lines III-III′ in FIG. 2A;

FIG. 3A is a sectional view taken along the line III-III′ of FIG. 2A and shows a non-limiting example of a first stage of a manufacturing method of a semiconductor device according to the first embodiment;

FIG. 3B is a sectional view taken along the line III-III′ of FIG. 2A and shows a non-limiting example of a second stage of a manufacturing method of a semiconductor device according to the first embodiment;

FIG. 3C is a sectional view taken along the line III-III′ of FIG. 2A and shows a non-limiting example of a third stage of a manufacturing method of a semiconductor device according to the first embodiment;

FIG. 4A is a plan view showing a semiconductor device according to a second illustrative embodiment of the present invention;

FIG. 4B is a sectional view taken along a line IV-IV′ of FIG. 4A and shows a semiconductor device according to the second embodiment of the present invention; and

FIG. 4C is a sectional view taken along a line IV-IV′ of FIG. 4A and shows a semiconductor device according to the second embodiment of the present invention.

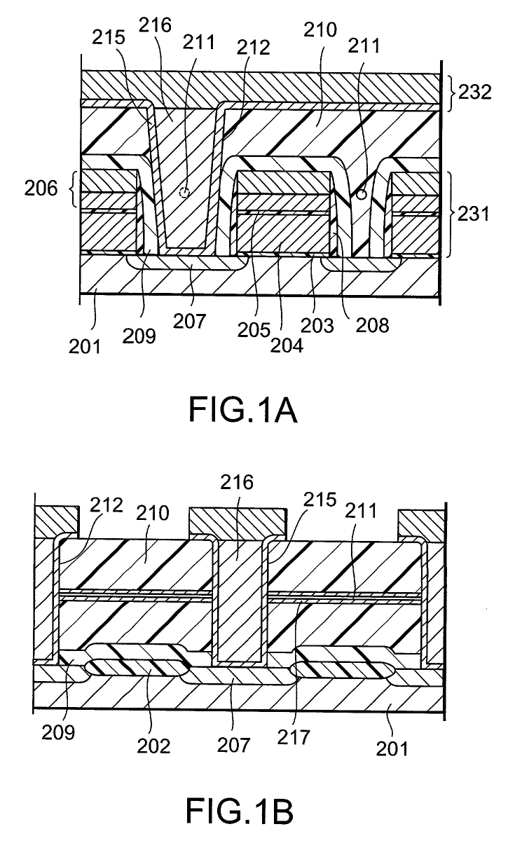

### BRIEF DESCRIPTION OF THE EMBODIMENTS

The following description of the embodiments discloses specific configurations, features, and operations. However, the embodiments are merely examples of the present invention, and thus, the specific features described below are merely used to more easily describe such embodiments and to provide an overall understanding of the present invention. Accordingly, one skilled in the art will readily recognize that the present invention is not limited to the specific embodiments described below. Furthermore, the descriptions of various configurations, features, and operations of the present invention that would have been known to one skilled in the art are omitted for the sake of clarity and brevity.

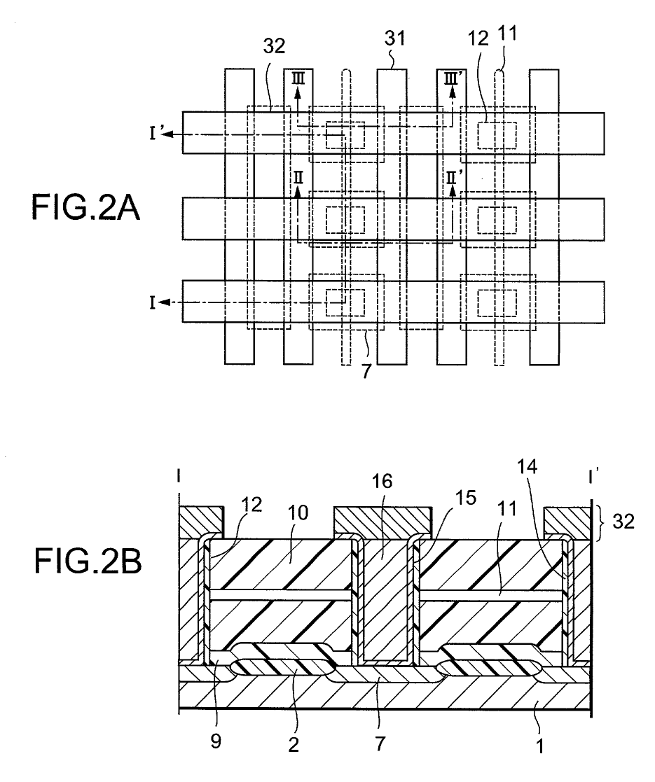

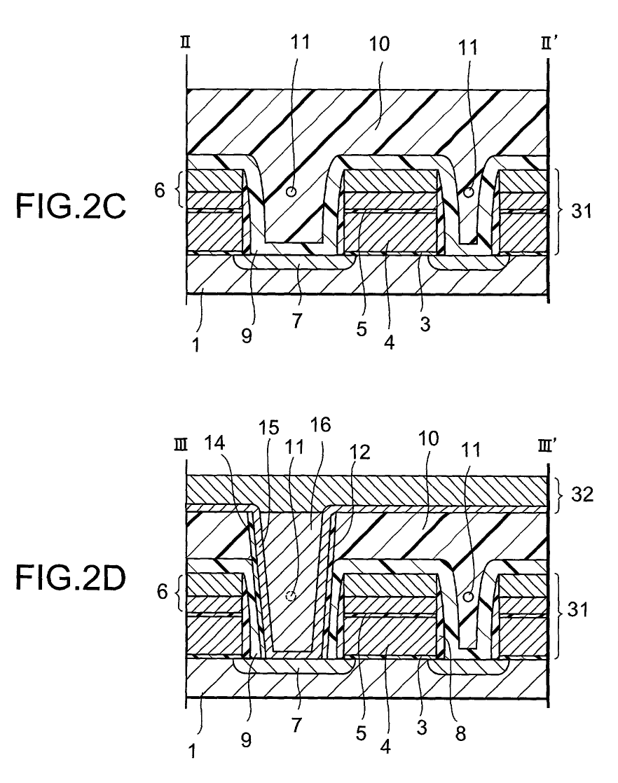

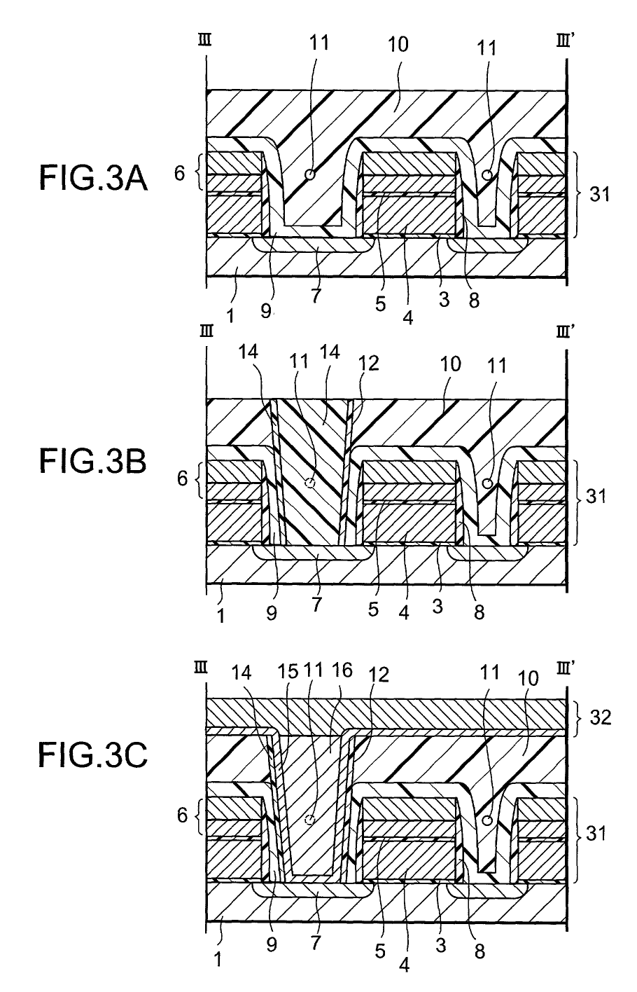

FIGS. 2A to 2B show a first illustrative, non-limiting embodiment of the present invention. In the first embodiment, a semiconductor device having a multi-layer wiring structure is provided in which a void is formed in an interlayer insulating film to reduce a parasitic capacitance between wirings in the device. Moreover, in the embodiment, the layout of the contact holes is not restricted, and the void does not create short-circuits between the wirings. In addition, FIGS. 3A to 3C show an example of a method for manufacturing the semiconductor device according to the first embodiment.

In the first embodiment, the semiconductor device corresponds to flash memory serving as a semiconductor nonvolatile memory and comprises three types of conductive layers (i.e. a source and drain diffusion layer, word lines, and bit lines). FIG. 2A is a plan view showing the semiconductor device according to the first embodiment, and FIG. 2B is a sectional view taken along a line I-I′ shown in FIG. 2A. Further, FIGS. 2C and 2D are sectional views respectively taken along lines II-II′ and III-III′ shown in FIG. 2A.

First, the manufacturing method of the first embodiment will be described in conjunction with FIGS. 3A to 3C, which are sectional views taken along the line III-III′ shown in FIG. 2A and which respectively show three manufacturing stages. As shown in FIG. 3A, wells (not shown) and field oxide films (not shown) are formed on a semiconductor substrate 1. Then, tunnel oxide films 3, floating gates 4, ONO films 5, and control gates 6 are sequentially formed over the substrate 1. The films 3 to 5 and gates 6 form word lines 31, and source and drain diffusion layers 7 are formed between the word lines 31. In a very specific non-limiting example, the width of each word line 31 is about 0.2 to 0.4 μm, the length of each word line 31 is about 0.2 to 0.4 μm, and a height of each word line 31 is about 0.4 to 0.5 μm.

As noted above, the terms “on” and “over” are to describe the orientation of various films and other components used to form the semiconductor device. Furthermore, although the first embodiment describes and illustrates a first film or layer being directly “on” or “over” a second film or layer, the terms “on” and “over” should not be limited to such a direct positioning or contact.

In any event, side walls 8 are formed on the sides of the word lines 31, and then, non-doped silicon oxide films 9, serving as interlayer insulating films, are grown between the word lines 31. Also, the films 9 are not thick enough to fill a space between word lines 31 but are thick enough to prevent the diffusion of impurities into the semiconductor substrate 1 from layers above the silicon oxide films 9.

Subsequently, BPSG films 10 are formed on the silicon oxide films 9 and are subjected to a heating operation. In a very specific, non-limiting example, the heating operation is performed at 800 C for 10 minutes, and the BPSG films 10 are subjected to a reflowing operation. Then, a CMP operation is performed to eliminate any unevenness on the BPSG films 10 to flatten surfaces of the films 10.

During or shortly after the operations above, voids 11 (or “nests”) are formed in the BPSG films 10 and in parallel with and between the word lines 31. (See, e.g., FIGS. 2B and 2C). Such voids 11 can be formed by adjusting a concentration of phosphorus and boron in the BPSG films 10, a reflowing temperature of the films 10, and a reflowing time when the BPSG films are formed. In a illustrative example, when the BPSG films 10 are stacked and the reflowing operation is performed at about 800 C for about 10 minutes, a concentration of phosphorus is 4 mol %, and a concentration of boron is 9 mol %, the voids 11 are formed with a diameter of about 0.2 μm.

Subsequently, as shown in FIG. 3B, the source and drain diffusion layer 7 is exposed by forming a contact hole (or through hole) 12 through the BPSG film 10 and the interlayer insulating film 9. Furthermore, as shown in FIGS. 2A and 3B, the contact hole 12 intersects a void 11.

Next, a silicon nitride film is grown on the bottom and the inner surfaces of the contact hole 12. In an non-limiting example, the film has a thickness of about 20 to 30 nm. Then, the silicon nitride film is etched back, and the inner wall of the opened contact hole 12 is covered with a side wall nitride film 14, which comprises the silicon nitride film.

Subsequently, as shown in FIG. 3C, the inner and bottom surfaces of the contact hole 12 are cleaned with, e.g., diluted hydrofluoric acid. Then, a laminated metal film 15, which comprises a composite material having titanium/titanium nitride, is sputtered as an adhesion layer. Thereafter, tungsten 16 is embedded in the contact hole 12, and a bit line 32 is formed so as to complete the flash memory semiconductor device.

In the illustrative, non-limiting example of the flash memory described above, the side wall nitride film 14 is provided on the inner wall of the contact hole 12. As a result, a short circuit between adjacent bit lines 32 can be prevented, even if the contact hole 12 intersects one or more voids 11. In addition, based such a design, a distance between the control gates 6 and a metal film embedded in the bit line contact or between the floating gates 4 and the metal film can be increased. As a result, the resistance to pressure building up between the gates 4 or 6 and the metal film is improved, and thus, the reliability of the flash memory is increased.

Further, the voids 11 are formed between the word lines 31 of the memory device. Thus, the voids 11 are lower in permittivity than the configuration where the BPSG films 10 entirely fill the space between the word lines 31. Consequently, the wiring capacitance between the word lines 31 is substantially reduced. Also, by forming the voids 11 in the BPSG films 10, the consumption of the BPSG film 10 is reduced by the volume of the voids 11. Consequently, after reflowing the BPSG films 10, excellent evenness can be achieved on the surface of the films 10. Additionally, in the case where a CMP operation is used to flatten the surface of the BPSG films 10, the BPSG films 10 are relatively constant in consumption per unit area over the entire semiconductor device. Therefore, absolute unevenness of the BPSG films 10 is small over a wide region (e.g., one chip), and the interlayer insulating film remaining after the CMP operation has been performed has a more even thickness.

The above description related to a semiconductor device in which the insulating side wall film 14 is formed on the inner wall of the contact hole 12. However, even if the insulating side wall film is not used, a conductive side wall film can be formed on the inner wall of the contact hole 12 as long as the shape of the void 11 or the condition of stacking metal films 15 satisfies the following condition: the metal film 15 stacked on the contact hole 11 does not enter the void 11, or if the metal film 15 enters the void 11, the entry is negligible in terms of short circuiting between the metal films 15 of adjacent contact holes 12. Also, the film 14 does not have to be formed on the entire inner surface of the contact hole 12.

Further, the above description is mainly directed to the situation in which a void 11 intersects a contact hole 12. However, some portions of the chip may be designed such that the interval between certain word lines 31 does not permit the formation of a void 11. For example, certain regions of the device may require the silicon oxide film 9 to have a thickness that is so large that it fills a large majority of the interval between the word lines 31 or may require an interval between word lines 31 to be relatively small. Clearly, one skilled in the art will understand that certain implementations of the present embodiment may include configurations in which voids are not formed between all of the word lines 31.

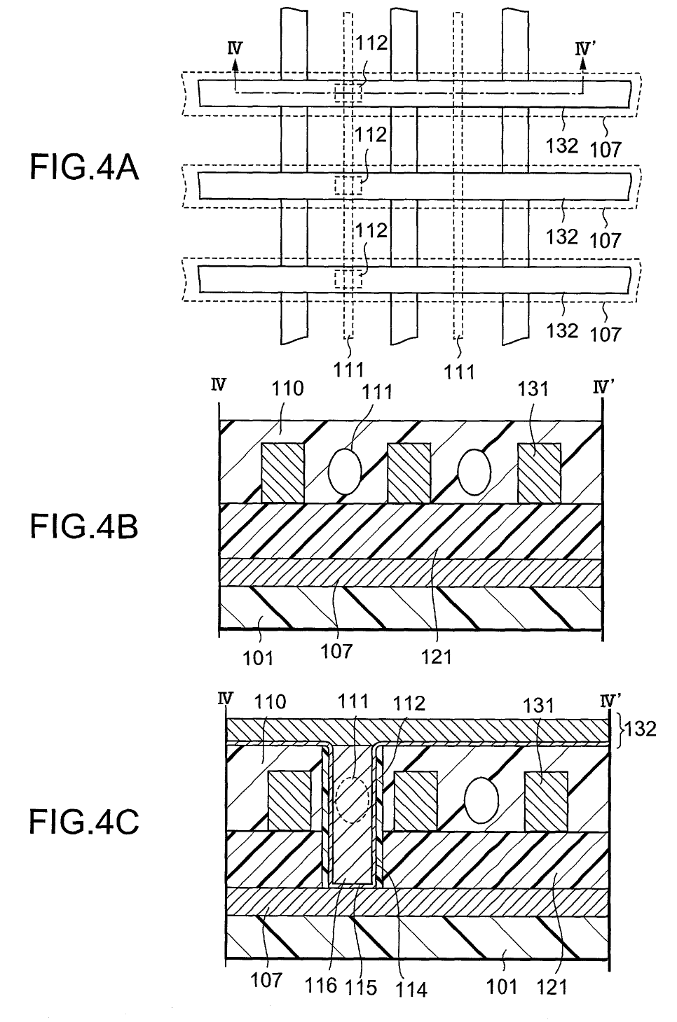

FIGS. 4A to 4C show a second, non-limiting embodiment of the present invention. The second embodiment relates to a semiconductor device having a three-layer wiring structure, and FIG. 4A is a plan view of the device. Also, FIGS. 4B and 4C are sectional views respectively showing first and second manufacturing stages and are taken along a line IV-IV′ shown in FIG. 4A. Moreover, FIGS. 4B and 4C show the configuration of a second layer wiring running in parallel at predetermined intervals, but the sectional view is taken along a line orthogonal to the running direction of the second layer wiring.

In one implementation, (1) the first layer wirings of the second embodiment may correspond to the source and drain diffusion layers 7 of the first embodiment, (2) the second layer wirings may correspond to the word lines 31 of the first embodiment, and (3) the third layer wirings may correspond to the bit lines 32 of the first embodiment. Thus, for the sake of convenience, components of the second embodiment that corresponds to the components of the first embodiment have the same reference numerals, except that the value of 100 is added to the reference numerals of the first embodiment. Nonetheless, such a corresponding designation of reference numerals should in no way be construed as any type of limitation of the present invention.

In any event, as shown in FIG. 4B, a first layer wiring 107 is formed on a base substrate 101, and a flattened first interlayer insulating film 121 is formed over the base substrate 101 and the first layer wiring 107. While the insulating film 121 may be a non-doped insulating film, it does not have to be when a lower surface of the film 121 does not directly contact an element formed on the semiconductor substrate 101. Thus, an insulating film having doped impurities can also be employed. After forming the film 121, a second layer wiring 131 is formed on the first interlayer insulating film 121.

Afterwards, a BPSG film 110 is grown to cover the first interlayer insulating film 121 and the second layer wiring 131 under the similar manufacturing conditions to those of the first embodiment. Subsequently, reflowing and flattening operations are performed on the BPSG film 110.

During or shortly after such operations, voids 111 are formed in the BPSG film 110 between and in parallel with the second layer wiring 131.

Subsequently, in order to expose the first layer wiring 107 through the BPSG film 110, a through hole 112 is formed that penetrates the BPSG film 110 and reaches the first layer wiring 107. As shown in FIGS. 4A and 4C, the through hole 112 intersects a void 111.

Next, as shown in FIG. 4C, a silicon nitride film is grown with a thickness of about 20 to 30 nm on the bottom and the inner walls of the through hole 112. Thereafter, the silicon nitride film is etched back, and the inner wall of the through hole 112 is covered with a side wall nitride film 114 composed of the silicon nitride film.

Then, the bottom and inner walls of the through hole 112 are cleaned, and subsequently, a laminated metal film 115 comprising a composite material including titanium/titanium nitride, is sputtered as a contact layer. Thereafter, tungsten 116 is filled in the through hole 112. Finally, the third layer wiring 132 is formed so as to complete the semiconductor device having a three-layer wiring.

In the semiconductor device described above, a side wall nitride film 114 is formed on the inner wall of the through hole 112. Accordingly, short circuits between adjacent through holes 112 corresponding to the third layer wiring 132 are prevented.

Further, voids 111 are formed between the second layer wiring 131. Thus, the wiring capacitance between wirings of the second layer wiring 131 is reduced for the reasons presented above. Also, the consumption of the BPSG film 110 is reduced, the evenness of the BPSG film is improved, and the thickness of the BPSG film 110 is more uniform after the CMP operation as discussed above.

The present invention is not limited to the above embodiments, and it is contemplated that numerous modifications may be made without departing from the spirit and scope of the invention. The semiconductor device, as described above with reference to the figures, is a merely an exemplary embodiment of the invention, and the scope of the invention is not limited to these particular embodiments. For example, the specific layers and materials that are used to create the semiconductor devices of the non-limiting embodiments are merely examples, and one skilled in the art will readily know that the present invention can be applied to devices containing different layers and materials. Accordingly, other structural configurations may be used, without departing from the spirit and scope of the invention as defined in the claims.

What is claimed:

1. A semiconductor device, comprising:
a first conductive layer formed on a substrate;
a first insulating layer formed on said first conductive layer;
a void formed in said first insulating layer;
a second conductive layer formed on said insulating layer;
a via hole formed in said first insulating layer between said first conductive layer and said second conductive layer, wherein a boundary of said via hole is connected to said void; and
a partition film formed on an inner surface of said via hole at said boundary between said void and said via hole.

2. The semiconductor device as claimed in claim 1, wherein a diameter of said via hole is larger than a cross-sectional width of said void, and
wherein said cross-sectional width is perpendicular to a longitudinal axis of said void.

3. The semiconductor device as claimed in claim 1, wherein said via hole divides said void into a first portion of said void and a second portion of said void.

4. The semiconductor device as claimed in claim 1, further comprising:
a second insulating layer formed on said first conductive layer;
a first middle conductive layer on said second insulating layer; and
a second middle conductive layer on said second insulating layer, wherein said first insulating layer covers said first middle conductive layer and said second middle conductive layer, and
wherein said void is arranged between said first middle conductive layer and said second middle conductive layer.

5. The semiconductor device as claimed in claim 4, wherein at least one part of said first middle conductive layer and at least one part of said second middle conductive layer are arranged substantially parallel to each other, and
wherein at least one part of said void is arranged between said one part of said first middle conductive layer and said one part of said second middle conductive layer.

6. The semiconductor device as claimed in claim 5, further comprising:
at least one side wall covering side surfaces of said first middle conductive layer and said second middle conductive layer.

7. The semiconductor device as claimed in claim 5, wherein said first conductive layer comprises a diffusion layer on said substrate,
wherein said second insulating layer comprises a gate insulating layer, and
wherein said first middle conductive layer and second middle conductive layer are word lines.

8. The semiconductor device as claimed in claim 5, wherein said first conductive layer comprises a diffusion layer on said substrate,
wherein said first insulating layer comprises a BPSG film, and
wherein said first middle conductive layer and second middle conductive layer are word lines.

9. The semiconductor device as claimed in claim 1, wherein said first insulating layer is made of silicon oxide including an impurity.

10. The semiconductor device as claimed in claim 1, further comprising:
an adhesion layer formed on said inner surface of said via hole, wherein said partition film is disposed between said boundary and said adhesion layer.

11. A semiconductor device, comprising:
a first lower wiring layer formed on a semiconductor substrate;
a second lower wiring layer formed on said semiconductor substrate, said second lower wiring layer arranged substantially parallel to said first lower wiring layer;
a diffusion layer arranged between said first lower wiring layer and said second lower wiring layer on said semiconductor substrate;
an insulating layer formed on said first lower wiring layer, said second lower wiring layer, and said diffusion layer;
a void formed in said insulating layer above said diffusion layer, said void being substantially parallel to said first lower wiring layer;
an upper wiring layer formed on said insulating layer;
a via hole formed in said insulating layer, wherein said via hole connects said diffusion layer to said upper wiring layer and wherein said via hole is connected to said void; and
a partition film covering an inner side surface of said via hole, said partition film located between said void and said via hole.

12. The semiconductor device as claimed in claim 11, wherein said upper wiring layer is arranged substantially perpendicular to said first lower wiring layer.

13. The semiconductor device as claimed in claim 11, wherein said first lower wiring layer comprises a floating gate and a control gate.

14. The semiconductor device as claimed in claim 11, further comprising:
a plurality of said diffusion layers arranged between said first lower wiring layer and said second lower wiring layer and arranged along said void; and
a plurality of isolating insulating layers on said semiconductor substrate, said plurality of isolating insulating layers separating said plurality of said diffusion layers from each other.

15. The semiconductor device as claimed in claim 14, further comprising:
a plurality of said upper wiring layers arranged substantially perpendicular to said first lower wiring layer;
a plurality of said via holes in said insulating layer, said plurality of said via holes connecting said plurality of said diffusion layers to said plurality of said upper wiring layers, wherein said plurality of said via holes are connected to said void; and
a plurality of said partition films covering inner side surfaces of said plurality of said via holes.

16. The semiconductor device as claimed in claim 15, further comprising:
a plurality of adhesion layers covering said plurality of said partition films; and
a plurality of conductive materials formed on said plurality of said adhesion layers in said via holes.

17. The semiconductor device as claimed in claim 15, wherein said plurality of said partition films electrically separate said plurality of said via holes from each other.

18. The semiconductor device as claimed in claim 15, wherein said first lower wiring line and said second lower wiring line are word lines in a memory cell.

19. A manufacturing method of a semiconductor device, comprising:
forming a first wiring and a second wiring on a substrate;
forming an insulating layer on said substrate between said first wiring and said second wiring;
heating said insulating layer to form a void in said insulating layer between said first wiring and said second wiring;
forming a via hole in said insulating layer, said via hole dividing said void into a first portion of said void and a second portion of said void; and
forming at least one partition film on an inner surface of said via hole to electrically separate said via hole from said first portion of said void.

20. The manufacturing method as claimed in claim 19, wherein said at least one partition film is formed in said inner surface to electrically separate said via hole from said second portion of said void.

21. The manufacturing method as claimed in claim 20, wherein said operation of forming said at least one partition film further comprises:
forming a partition layer on said inner surface of said via hole and a bottom surface of said via hole; and
removing a portion of said partition layer from said bottom surface of said via hole to form said at least one partition film.

22. The manufacturing method as claimed in claim 20, further comprising:
forming an adhesive layer on said inner surface of said via hole such that said at least one partition film is formed between said adhesive layer and said first and second portions of said void; and
filling said via hole with a conductive material.

23. The manufacturing method as claimed in claim 20, further comprising:
forming an upper wiring on said insulating layer, wherein said upper wiring is connected to said via hole.

24. The manufacturing method as claimed in claim 20, wherein said at least one partition film is an insulating film.

25. The manufacturing method as claimed in claim 24, wherein said at least one partition film is a silicon oxide layer.

26. The manufacturing method as claimed in claim 20, wherein a diameter of said via hole is larger than a cross-sectional width of said void in a direction that is perpendicular to a longitudinal axis of said void.

27. The manufacturing method as claimed in claim 20, wherein said heating performed under about 800° C. for about 10 minutes.

28. The manufacturing method as claimed in claim 20, further comprising:
forming a lower wiring on said substrate before forming said first wiring and said second wiring; and
forming a lower insulating layer on said substrate before forming said first wiring and said second wiring;
wherein forming said via hole operation comprises:
removing a portion of said insulating layer after forming said lower insulating layer; and
removing a portion of said lower insulating layer to expose said lower wiring after removing a portion of said insulating layer.

29. The manufacturing method as claimed in claim 20, further comprising:
forming a diffusion layer in said substrate; and
forming a gate insulating layer on said substrate,
wherein said first wiring is formed on said gate insulating layer, and
wherein said diffusion layer is exposed at a bottom of said via hole.

30. The manufacturing method of semiconductor device, comprising:
forming a first lower wiring and a second lower wiring, said second lower wiring arranged parallel to said first lower wiring on a substrate;
forming a plurality of isolation insulating layers on said substrate between said first lower wiring and said second lower wiring;
forming a plurality of diffusion layers in said substrate between said first lower wiring and said second lower wiring, said plurality of diffusion layers being separated from each other by said plurality of isolation insulating layers;
forming a first side wall on a side surface of said first lower wiring and a second side wall on a side surface of said second lower wiring;
forming an insulating layer covering an upper surface of said first lower wiring, said first side wall, an upper surface of said second lower wiring, and said second side wall;
forming an interlayer insulating layer to cover said insulating layer;
heating said interlayer insulating layer to form a void into said interlayer insulating layer between said first lower wiring and a second lower wiring;
removing a portion of said interlayer insulating layer to form at least one via hole penetrating said interlayer insulating layer to expose at least one of said plurality of diffusion layers;
forming an insulating film on an inner surface of said via hole and a surface of said at least one of said plurality of diffusion layers;
removing said insulating film on said surface of said diffusion layer;
forming a metal layer on said inner surface of said via hole;
burying a conductive material into said via hole; and
forming an upper wiring on said interlayer insulating layer to connect to said conductive material.
